(19) United States
(12) Patent Application Publication
(10) Pub. No.: US 2026/0215179 A1
(43) Pub. Date: Jul. 23, 2026

(54) Pattern Forming Method and Pattern Forming Apparatus

(71) Applicant: Tokyo Electron Limited, Tokyo (JP)

(72) Inventors: Takeya INOUE, Yamanashi (JP); Koji AKIYAMA, Yamanashi (JP); Kenji SEKIGUCHI, Yamanashi (JP)

(21) Appl. No.: 19/568,875

(22) Filed: Mar. 17, 2026

Related U.S. Application Data
(63) Continuation of application No. PCT/JP2024/031541, filed on Sep. 3, 2024.

(30) Foreign Application Priority Data
Sep. 27, 2023 (JP) 2023-166462

(51) Int. Cl. H10P 14/46; C25F 3/08; C25F 3/12

(52) U.S. Cl. CPC H10P 14/46; C25F 3/08; C25F 3/12

(57) ABSTRACT

There is a pattern forming method which includes: preparing a substrate having a second conductive layer on a surface of the substrate on which a pattern of a first conductive layer and an insulating layer is formed, supplying an ionic liquid to the surface of the substrate, and forming a pattern of the second conductive layer on the first conductive layer by causing a current to flow to the first conductive layer through the ionic liquid.

### CROSS-REFERENCE TO RELATED APPLICATIONS

This application is a bypass continuation application of International Application No. PCT/JP2024/031541 having an international filing date of Sep. 3, 2024 and designating the United States, the International Application being based upon and claiming the benefit of priority from Japanese Patent Application No. 2023-166462 filed on Sep. 27, 2023, the entire contents of which are incorporated herein by reference.

### TECHNICAL FIELD

The present disclosure relates to a pattern forming method and a pattern forming apparatus.

### BACKGROUND

For example, Japanese Laid-open Patent Publication No. H08-078396 discloses processing of a Ru film or a RuO₂ film into a desired pattern by the following multiple processes. First, a Ru film or a RuO₂ film is formed on a Si substrate by sputtering and, then, an SOG film is applied and a photosensitive material is coated thereon. Next, a resist pattern is formed using an exposure device. Then, the SOG film is patterned using an ECR dry etching apparatus. Thereafter, the resist pattern is removed by oxygen plasma ashing to form an etching mask of the SOG film, and the Ru film or the RuO₂ film is processed into a desired pattern using plasma of a mixed gas of oxygen and chlorine.

### SUMMARY

The present disclosure provides a technique capable of forming a pattern of a second conductive layer on a first conductive layer by utilizing a difference in adhesion between layers in a substrate on which a pattern of the first conductive layer and an insulating layer is formed.

In accordance with an exemplary embodiment of the present disclosure, there is a pattern forming method. The pattern forming method comprises: preparing a substrate having a second conductive layer on a surface of the substrate on which a pattern of a first conductive layer and an insulating layer is formed, supplying an ionic liquid to the surface of the substrate, and forming a pattern of the second conductive layer on the first conductive layer by causing a current to flow to the first conductive layer to which the ionic liquid has been supplied.

### BRIEF DESCRIPTION OF THE DRAWINGS

FIGS. 1A, 1B, 1C, 1D, and 1E are diagrams illustrating an example of experimental results of pattern formation on a substrate using an ionic liquid according to one embodiment.

FIGS. 2A and 2B are diagrams illustrating another example of pattern formation on a substrate using an ionic liquid according to one embodiment.

FIG. 3 is a schematic diagram illustrating an example of a pattern forming apparatus according to a first embodiment.

FIGS. 4A, 4B, and 4C are diagrams illustrating an example of pattern formation of a metal layer by the pattern forming apparatus of FIG. 3.

FIG. 5 is a schematic diagram illustrating an example of a pattern forming apparatus according to a second embodiment.

FIGS. 6A, 6B, and 6C are diagrams illustrating an example of pattern formation of a metal layer by the pattern forming apparatus of FIG. 5.

FIG. 7 is a flowchart illustrating an example of a pattern forming method using the pattern forming apparatus according to the first embodiment.

FIG. 8A is a diagram illustrating an example of application of the pattern forming method according to the first embodiment to a process.

FIG. 8B is a diagram illustrating another example of application of the pattern forming method according to the first embodiment to a process.

FIG. 9 is a flowchart illustrating an example of a pattern forming method using a pattern forming apparatus according to the second embodiment.

FIG. 10A is a diagram illustrating an example of application of the pattern forming method according to the second embodiment to a process.

FIG. 10B is a diagram illustrating another example of application of the pattern forming method according to the second embodiment to a process.

FIG. 10C is a diagram illustrating another example of application of the pattern forming method according to the second embodiment to a process.

FIG. 10D is a diagram illustrating another example of application of the pattern forming method according to the second embodiment to a process.

FIG. 11A is a diagram illustrating another process application example.

FIG. 11B is a diagram illustrating another process application example.

FIG. 11C is a diagram illustrating another process application example.

FIG. 11D is a diagram illustrating another process application example.

### DETAILED DESCRIPTION

Hereinafter, embodiments for implementing the present disclosure will be described with reference to the accompanying drawings. Throughout the drawings, like reference numerals will be used for like parts, and redundant description thereof may be omitted.

### Pattern Formation on Substrate Using Ionic Liquid

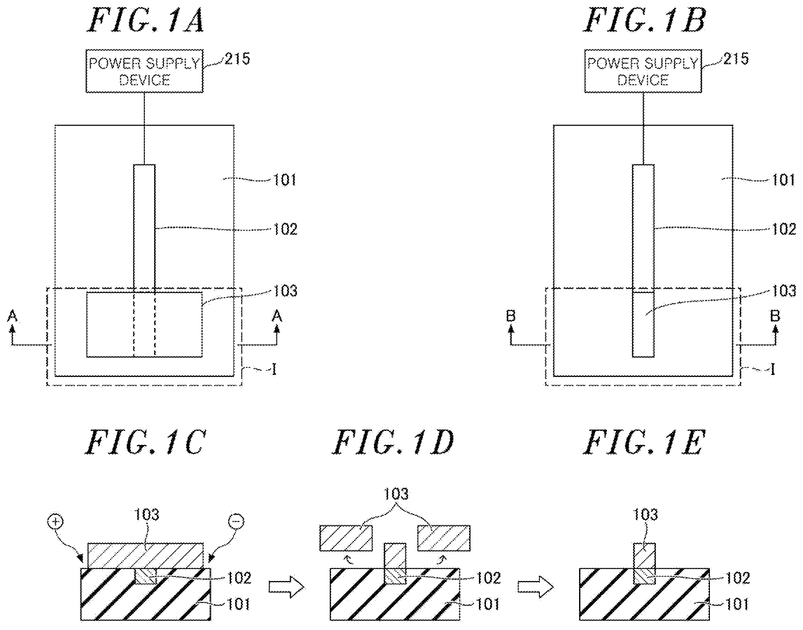

An example of experimental results of pattern formation of a conductive layer on a substrate using an ionic liquid according to one embodiment will be described with reference to FIGS. 1A to 1E. FIGS. 1A to 1E are diagrams illustrating an example of experimental results of pattern formation on a substrate using an ionic liquid according to one embodiment.

FIG. 1A is a top view illustrating a stacked structure of films on a substrate before the experiment. FIG. 1C is a diagram illustrating the A-A cross section of the stacked structure of FIG. 1A. FIG. 1B is a top view illustrating the stacked structure of the films on the substrate after the experiment. FIG. 1E is a diagram illustrating the B-B cross section of the stacked structure of FIG. 1B. FIG. 1D is a cross-sectional view of the stacked structure during the experiment.

In the experiment, as shown in FIGS. 1C to 1E, the stacked structure in which a second conductive layer 103 such as Ru was formed on a structure in which a first conductive layer 102 such as TiN was embedded in a recess of an insulating layer 101 such as SiO₂ or Low-k on a substrate was immersed in an ionic liquid I containing EMIM.

In this state, a current was caused to flow from a power supply device 215 to the first conductive layer 102 through the ionic liquid I. As a result, the ionic liquid I, which has a property of easily penetrating, entered the gap between the insulating layer 101 and the second conductive layer 103, thereby peeling off the second conductive layer 103 on the insulating layer 101.

Specifically, when one electrode connected to the power supply device 215 was inserted into the ionic liquid I and the other electrode was brought into contact with the first conductive layer 102 to cause a current to flow, cations (positive ions) and anions (negative ions) in the ionic liquid I were drawn toward the vicinity of the first conductive layer 102, as shown in FIG. 1C. The first conductive layer 102 and the second conductive layer 103 are the same conductor material, and the interface therebetween has higher adhesion compared to the interface between the insulating layer 101 and the second conductive layer 103.

As a result of cations and anions entering the interface between the insulating layer 101 and the second conductive layer 103, which has lower adhesion compared to the interface between the first conductive layer 102 and the second conductive layer 103, the second conductive layer 103 on the insulating layer 101 peeled off, as shown in FIG. 1D. Cations and anions did not enter the interface between the first conductive layer 102 and the second conductive layer 103, which has higher adhesion, so that peeling off did not occur. As a result, as shown in FIG. 1E, due to the peeling off of the second conductive layer 103 on the insulating layer 101, only the second conductive layer 103 on the first conductive layer 102, which has higher adhesion, selectively remained, thereby forming a pattern of the second conductive layer 103.

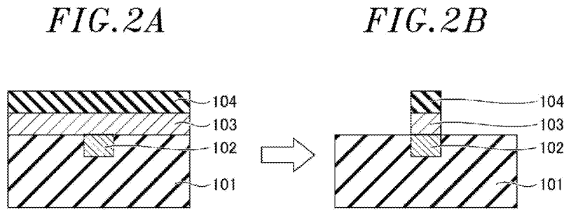

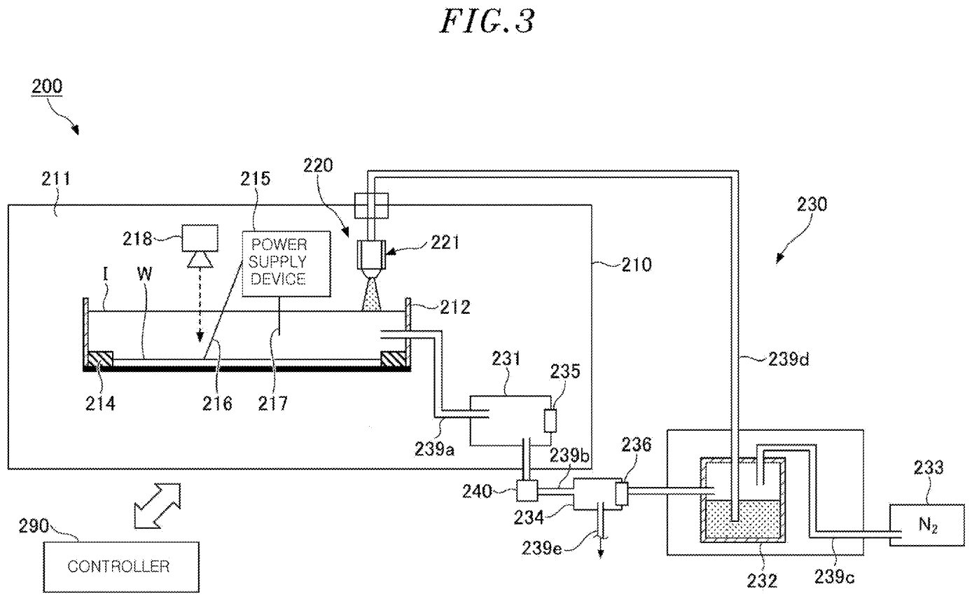

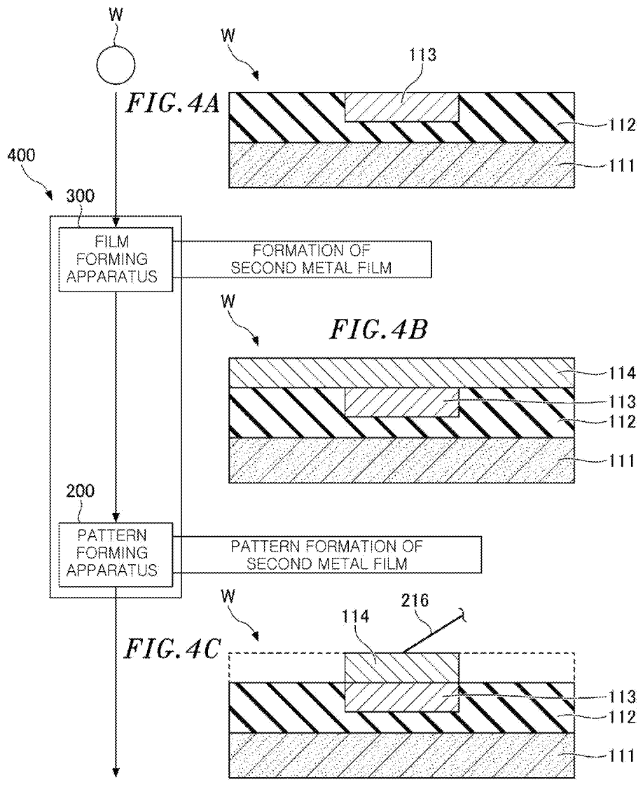

In a state where another film is further deposited on the second conductive layer 103, the second conductive layer 103 and another film can be peeled off at once from the interface with the insulating layer 101 to form a pattern of the second conductive layer 103 and another film. FIGS. 2A and 2B illustrates another example of pattern formation on a substrate using an ionic liquid. For example, in FIG. 2A, another film 104 is formed on the second conductive layer 103. The film 104 may be a metal film or an insulating film. The adhesion between the layer 104 and the second conductive layer 103 does not matter. When the same experiment as that in FIGS. 1A-1E is performed on the structure shown in FIG. 2A, both the second conductive layer 103 and another film 104 on the insulating layer 101 are peeled off together. As a result, as shown in FIG. 2B, only the second conductive layer 103 and another film 104 on the first conductive layer 102, which have higher adhesion, selectively remain, and the second conductive layer 103 and the film 104 on the insulating layer 101, which have lower adhesion, are peeled off at once, thereby forming the second conductive layer 103 and the film 104 on the pattern of the first conductive layer 102.

The second conductive layer 103 may be any one of a noble metal, tungsten, molybdenum, or copper (Cu). The second conductive layer 103 may be a noble metal. The noble metal may be any one of gold (Au), silver (Ag), platinum (Pt), palladium (Pd), rhodium (Rh), iridium (Ir), ruthenium (Ru), or osmium (Os).

In particular, noble metals are difficult to process by wet etching and are also difficult to process by dry etching. When the second conductive layer 103 made of a noble metal is dry-etched, plasma irradiation is required. Therefore, some degree of damages occurs to the substrate or the insulating layer 101, such as SiO₂, under the second conductive layer 103. In contrast, in the pattern forming method, plasma is not used, so that the insulating layer 101 is less damaged. In addition, by peeling off (lifting off) the second conductive layer 103 on the insulating layer 101, it is possible to easily perform pattern formation of materials such as noble metals that are difficult to pattern by etching. Further, in the pattern forming method, there is no concept of selectivity, and even if the second conductive layer 103 is made of a material for which selectivity cannot be achieved by plasma etching, the pattern formation can be performed by utilizing a difference in adhesion between layers. As a result, the second conductive layer 103 can be patterned simply by immersing the substrate having the second conductive layer 103 on the surface thereof where the pattern of the first conductive layer 102 and the insulating layer 101 is formed in the ionic liquid I and controlling the current. Hence, it is possible to omit a conventional process of separately patterning the second conductive layer 103.

After the experiment, a film of the second conductive layer 103 was floating in the ionic liquid I. Therefore, it is considered that the second conductive layer 103 was peeled off rather than having been dissolved. In other words, the second conductive layer 103 remained in the ionic liquid in its original metallic form, rather than as an altered by-product caused by chemical reaction. Therefore, according to the pattern forming method, the peeled second conductive layer 103 in the ionic liquid I can be recovered and reused.

### First Embodiment

### Pattern Forming Apparatus

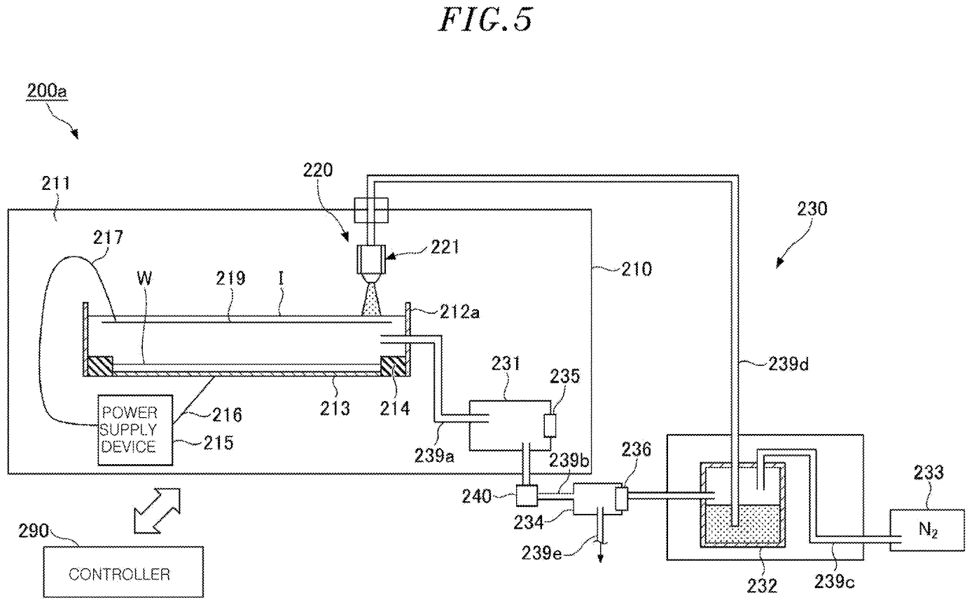

Next, an example of a pattern forming apparatus for performing a pattern forming method using the ionic liquid I will be described with reference to FIGS. 3 and 4A-4C. FIG. 3 is a schematic diagram illustrating an example of a pattern forming apparatus 200 according to a first embodiment. FIGS. 4A-4C are diagrams illustrating an example of pattern formation of a metal layer by the pattern forming apparatus 200 of FIG. 3. In the first embodiment, as shown in FIGS. 4A-4C, a pattern forming system 400 includes a film forming apparatus 300 and the pattern forming apparatus 200.

A substrate W shown in FIG. 4A has a structure in which a Low-k film 112 is formed on a silicon substrate 111, and a first metal film 113 is embedded in a recess of the Low-k film 112. The Low-k film 112 is an example of an insulating layer. The first metal film 113 is, for example, a metal wiring, and is an example of a first conductive layer. The first metal film 113 may be Ti, TiN, TaN, or the like.

The substrate W on which the pattern of the Low-k film 112 and the first metal film 113 is formed is transferred to the film forming apparatus 300. The film forming apparatus 300 forms a second metal film 114 on the surface of the substrate W. The second metal film 114 is, for example, a metal wiring, and is an example of a second conductive layer. The second metal film 114 may be Ru, Pt, Cu, W, Mo, or the like. The film forming apparatus 300 may be a physical vapor deposition (PVD) apparatus, a chemical vapor deposition (CVD) apparatus, or an atomic layer deposition (ALD) apparatus. The film forming apparatus 300 may also be a plasma processing apparatus such as a capacitively coupled plasma (CCP) processing apparatus or an inductively coupled plasma (ICP) processing apparatus.

As a result, as shown in FIG. 4B, the second metal film 114 is formed on the pattern of the first metal film 113 and the Low-k film 112 on the substrate W. The substrate W having the second metal film 114 on the surface of the substrate W on which the pattern of the first metal film 113 and the Low-k film 112 is formed is loaded into the pattern forming apparatus 200, and the pattern formation of the second metal film 114 is performed in the pattern forming apparatus 200. The pattern forming apparatus 200 of FIG. 3 is an example of an apparatus for performing pattern formation of the second metal film 114. The pattern forming apparatus 200 includes a chamber 210, a liquid supply part 220, a liquid circulation part 230, and a controller 290.

The chamber 210 forms a processing space 211 having a sealed structure. The interior of the chamber 210 is evacuated and maintained in a vacuum state (depressurized state) by an exhaust system (not shown) including a pressure control valve and a vacuum pump. Alternatively, the interior of the chamber 210 may be filled with an inert gas, such as N2 gas, supplied from an inert gas supply part (not shown), thereby forming an atmosphere of the inert gas.

A processing tank 212 is provided in the chamber 210. The substrate W transferred into the chamber 210 is accommodated in the processing tank 212. An insulating holding jig 214 is located at the outer periphery of the bottom surface of the processing tank 212. The holding jig 214 holds the substrate W in a substantially horizontal state.

The liquid supply part 220 may include a slit nozzle 221. The slit nozzle 221 supplies the ionic liquid I into the processing tank 212. As a result, the substrate W is immersed in the ionic liquid I stored in the processing tank 212. Supplying the ionic liquid includes both immersion and coating. The liquid supply part 220 does not necessarily include the slit nozzle 221, and may include a simple nozzle.

The liquid circulation part 230 collects the ionic liquid stored in the processing tank 212 and supplies it to the slit nozzle 221. The liquid circulation part 230 includes a compressor 231, an ionic liquid tank 232, a carrier gas supply source 233, a cleaning part 234, and pH sensors 235 and 236.

The compressor 231 is connected to the processing tank 212 through a line 239a, collects the ionic liquid I stored in the processing tank 212, and compresses the ionic liquid I to, for example, a pressure equal to or greater than atmospheric pressure. The compressor 231 is connected to the ionic liquid tank 232 through a line 239b, and transfers the compressed ionic liquid to the ionic liquid tank 232 through the line 239b. The ionic liquid tank 232 stores the ionic liquid. A valve and a flow rate controller (both not shown) are provided in the line 239b. For example, by controlling opening and closing of the valve, the transfer of the ionic liquid from the compressor 231 to the ionic liquid tank 232 is periodically performed.

One ends of the lines 239b to 239d are inserted into the ionic liquid tank 232. The other end of the line 239b is connected to the compressor 231, and the ionic liquid compressed by the compressor 231 is supplied to the ionic liquid tank 232 through the line 239b. The other end of the line 239c is connected to the carrier gas supply source 233, and a carrier gas such as N2 gas is supplied from the carrier gas supply source 233 to the ionic liquid tank 232 through the line 239c. By bubbling N₂ gas in the ionic liquid tank 232, ionic liquid with reduced dissolved oxygen can be supplied into the processing tank 212. Instead of bubbling in the ionic liquid tank 232, the ionic liquid in the processing tank 212 may be subjected to N2 bubbling to reduce dissolved oxygen. Through N2 bubbling, the quality of the ionic liquid I can be improved. However, it is unnecessary to supply a carrier gas such as N₂ gas to the ionic liquid tank 232.

The other end of the line 239d is connected to the slit nozzle 221, and the ionic liquid in the ionic liquid tank 232 is transferred to the slit nozzle 221 together with the carrier gas through the line 239d. Valves, flow rate controllers (not shown), and the like are provided in the lines 239b to 239d.

A recovery filter 240 and the cleaning part 234 are provided in the line 239b. The recovery filter 240 is located on the compressor 231 side relative to the cleaning part 234, and recovers the second metal film 114 contained in the ionic liquid I transferred from the compressor 231. The second metal film 114 peeled off in the processing tank 212 can be recovered by the recovery filter 240 and reused.

The cleaning part 234 cleans the ionic liquid after the recovery of the second metal film 114. A drain line 239e is connected to the cleaning part 234, and ionic liquid whose characteristics have deteriorated is discharged through the drain line 239e. For example, the cleaning part 234 controls whether to reuse or discharge the ionic liquid based on the detection value of the pH sensor 236. Alternatively, for example, the cleaning part 234 may control whether to reuse or discharge the ionic liquid based on the detection value of the pH sensor 235. Alternatively, for example, the cleaning part 234 may control whether to reuse or discharge the ionic liquid based on the detection values of both the pH sensor 235 and the pH sensor 236.

The pH sensor 235 is provided in the compressor 231, and detects a hydrogen ion index (pH) of the ionic liquid in the compressor 231.

The pH sensor 236 is provided in the cleaning part 234 and detects the hydrogen index (pH) of the ionic liquid in the cleaning part 234.

The controller 290 performs the pattern formation process based on a computer-executable program executed by the pattern forming apparatus 200. The controller 290 may be configured to control individual elements of the pattern forming apparatus 200 to perform pattern formation of the metal film by immersing the substrate in the ionic liquid I. The controller 290 includes, for example, a computer. The computer includes, for example, a CPU, a storage part, and a communication interface.

The pattern forming apparatus 200 includes the power supply device 215 and electrodes 216 and 217 connected to the power supply device 215. One electrode 217 is inserted into the ionic liquid I. The probe (needle) at the tip end of the other electrode 216 is brought into contact with the second metal film 114 located directly on the first metal film 113 of the substrate W, as shown in FIG. 4C, while monitoring the position of the probe by a camera 218. The camera 218 may monitor the position of the probe from the outside of the chamber 210.

The camera 218 may detect the position of the first metal film 113 before the second metal film 114 is formed. In this case, after the second metal film 114 is formed, the probe at the tip end of the electrode 216 is brought into contact with the second metal film 114 located directly on the first metal film 113 based on the detected position of the first metal film 113.

Since the second metal film 114 is a thin film, the camera 218 may detect the position of the first metal film 113 after the second metal film 114 is formed. In this case as well, the probe at the tip end of the electrode 216 is brought into contact with the second metal film 114 located directly on the first metal film 113 based on the detected position of the first metal film 113.

The camera 218 may monitor a notch formed at the substrate W, and predict the position of the first metal film 113 from the position of the notch. Alternatively, an alignment mark may be provided in advance at the substrate, and the camera 218 may predict the position of the first metal film 113 based on the position of the alignment mark.

In both cases, the probe at the tip end of the electrode 216 is brought into contact with the second metal film 114 located directly on the first metal film 113 based on the predicted position of the first metal film 113.

After the position of the first metal film 113 is detected by the camera 218, the ionic liquid I may be supplied into the processing tank 212. Alternatively, the position of the first metal film 113 may be detected by the camera 218 after the ionic liquid I is supplied into the processing tank 212.

A current is caused to flow from the power supply device 215 to the first metal film 113 through the ionic liquid I and the second metal film 114. Accordingly, due to the difference in adhesion between the Low-k film 112 and the second metal film 114 and the adhesion between the first metal film 113 and the second metal film 114, the second metal film 114 on the Low-k film 112 is peeled off from the surface of the substrate W. As a result, as shown in FIG. 4C, the second metal film 114 remains only directly on the first metal film 113, thereby forming a pattern of the second metal film 114.

In the case of the back-end-of-line process of semiconductor processing, the substrate W has a structure in which an insulating film such as the Low-k film 112 is interposed between the silicon substrate 111 and the first metal film 113. In this case as well, in the pattern forming apparatus 200 shown in FIG. 3, a current can be caused to flow to the first metal film 113 by inserting one electrode into the ionic liquid and bringing the other electrode into contact with the surface of the substrate W.

### Second Embodiment

### Pattern Forming Apparatus

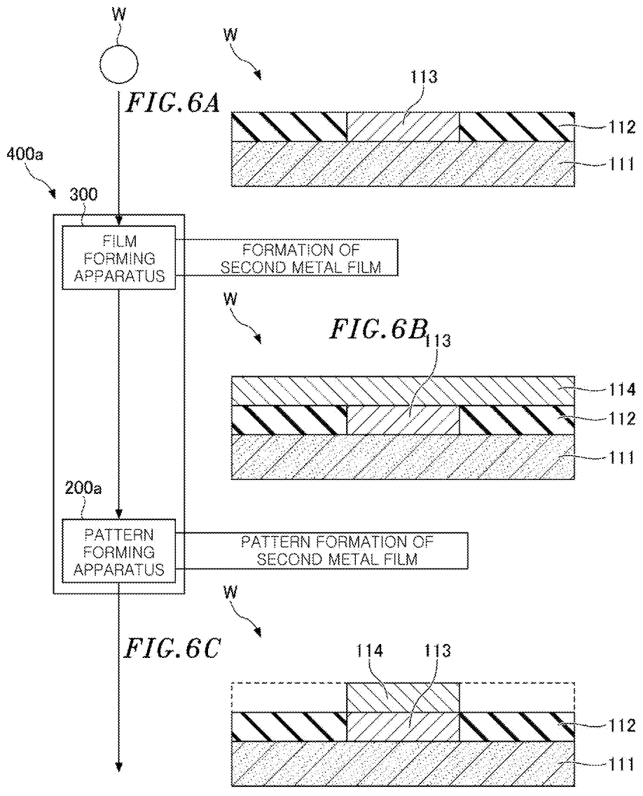

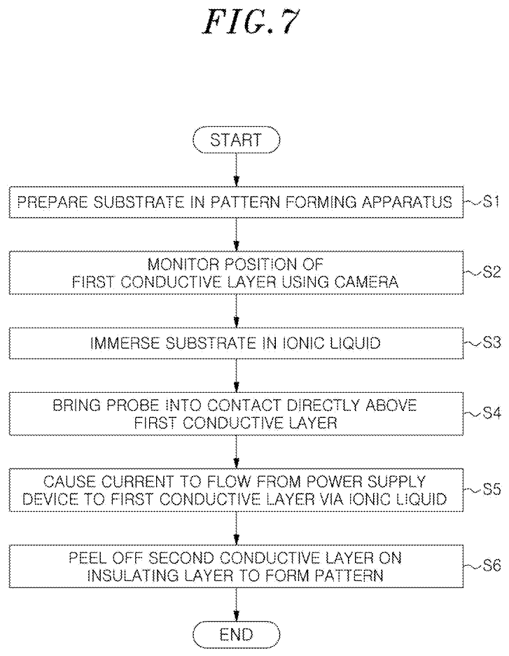

Next, another example of a pattern forming apparatus that performs a pattern forming method using the ionic liquid I will be described with reference to FIGS. 5 and 6A-6C. FIG. 5 is a schematic diagram illustrating an example of a pattern forming apparatus 200a according to a second embodiment. FIGS. 6A-6C are diagrams illustrating an example of pattern formation of a metal layer by the pattern forming apparatus 200a shown in FIG. 5. In the second embodiment, as shown in FIGS. 6A-6C, the film forming apparatus 300 and the pattern forming apparatus 200a constitute a pattern formation system 400a.

The substrate W shown in FIG. 6A has a pattern of the Low-k film 112 and the first metal film 113 formed on the silicon substrate 111. The substrate W having the pattern of the Low-k film 112 and the first metal film 113 is transferred to the film forming apparatus 300. The film forming apparatus 300 forms the second metal film 114 on the surface of the substrate W.

As a result, as shown in FIG. 6B, the second metal film 114 is formed on the surface of the substrate W on which a pattern of the first metal film 113 and the Low-k film 112 is formed. The substrate W on which the second metal film 114 is formed is transferred to the pattern forming apparatus 200a shown in FIG. 5. The pattern forming apparatus 200a includes a chamber 210, a liquid supply part 220, a liquid circulation part 230, and a controller 290.

The configurations of the chamber 210, the liquid supply part 220, the liquid circulation part 230, and the controller 290 of the pattern forming apparatus 200a are the same as the corresponding configurations of the pattern forming apparatus 200 shown in FIG. 3, so the description thereof will be omitted. Hereinafter, a processing tank 212a, the power supply device 215, and the electrodes 216 and 217, which have different configurations or arrangements from those of the pattern forming apparatus 200 shown in FIG. 3, will be described. In the pattern forming apparatus 200a shown in FIG. 5, a structure for monitoring the probe position of the electrode 216, such as the camera 218, is unnecessary.

The processing tank 212a has a metal plate 213 on the bottom surface thereof. The metal plate 213 is in contact with the backside of the substrate W, and electrically connects the electrode 216 connected to the power supply device 215 to the backside of the substrate W.

In the pattern forming apparatus 200a, one electrode 217 is inserted into the ionic liquid I. A metal mesh plate 219 is provided in the ionic liquid I, and the electrode 217 is brought into contact with the plate 219. However, the plate 219 may not be provided, the electrode 217 may be inserted into the ionic liquid I as in the electrode 217 shown in FIG. 3. The probe (needle) at the tip end of the other electrode 216 is brought into contact with the back surface of the metal plate 213.

The power supply device 215 causes electricity to flow to the first metal film 113 through the ionic liquid I. In the present embodiment, as shown in FIG. 6B, the front surface and the backside of the substrate W are electrically connected via the silicon substrate 111, the first metal film 113, and the second metal film 114. Therefore, by bringing the probe at the tip end of the electrode 216 into contact with the metal plate 213, electricity can flow to the first metal film 113 through the ionic liquid I.

Due to the difference in adhesion between the Low-k film 112 and the second metal film 114 and the adhesion between the first metal film 113 and the second metal film 114, the second metal film 114 on the Low-k film 112 is peeled off from the surface of the substrate W. As a result, as shown in FIG. 6C, only the second metal film 114 remains directly on the first metal film 113, thereby forming a pattern of the second metal film 114.

Thus, when electrical conduction between the front surface and the backside of the substrate W is established, the pattern formation of the second metal film 114 can be performed using the pattern forming apparatus 200a according to the second embodiment.

In the front-end-of-line of semiconductor processing, the substrate W has a structure in which electrical conduction between the front and back surfaces of the substrate W can be obtained. In this case, by inserting one electrode into the ionic liquid and bringing the other electrode into contact with the metal plate 213 a current can be caused to flow to the first metal film 113 using the pattern forming apparatus 200a shown in FIG. 5. When electrical conduction between the front surface and the back side of the substrate W can be obtained, a current can also be caused to flow to the first metal film 113 using the pattern forming apparatus 200 shown in FIG. 3.

### Pattern Forming Method Using Pattern Forming Apparatus According to First Embodiment

An example of a pattern forming method using the pattern forming apparatus 200 according to the first embodiment will be described with reference to FIG. 7. FIG. 7 is a flowchart illustrating an example of a pattern forming method using the pattern forming apparatus 200 according to the first embodiment. The pattern forming method shown in FIG. 7 is controlled by the controller 290.

In the pattern forming method of FIG. 7, in step S1, a substrate W having a second conductive layer on a surface thereof where a pattern of the first conductive layer and the insulating layer is formed is prepared.

In step S2, the position of the first conductive layer is monitored using the camera 218. In step S3, the ionic liquid is supplied to the processing tank 212, and the surface of the substrate W is immersed in the ionic liquid.

In step S4, the probe at the tip end of the electrode 216 connected to the power supply device 215 is brought into contact with the second conductive layer located directly on the first conductive layer based on the monitored position of the first conductive layer. The other electrode 217 connected to the power supply device 215 is inserted into the ionic liquid.

In step S5, a current is caused to flow from the power supply device 215 to the first conductive layer via the ionic liquid I. Accordingly, in step S6, due to the difference in adhesion between the insulating layer and the second conductive layer and the adhesion between the first conductive layer and the second conductive layer, the second conductive layer on the insulating layer is peeled off from the surface of the substrate W. As a result, the second conductive layer remains only on the first conductive layer, thereby forming a pattern of the second conductive layer.

### Process Application Example

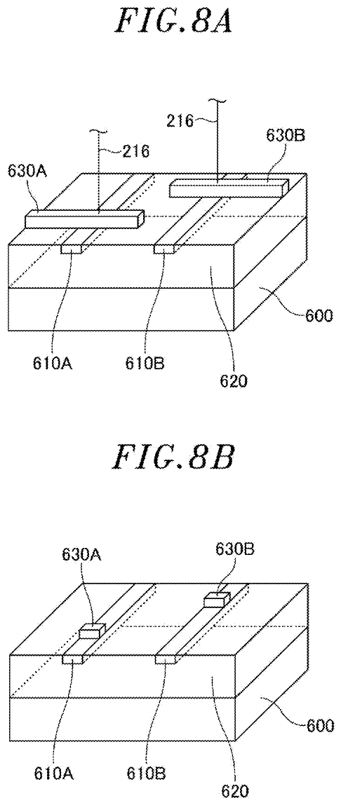

FIGS. 8A and 8B show an example of application of the pattern forming method according to the first embodiment to a process. In the prepared substrate W, as shown in FIG. 8A, an insulating layer 620 is formed on a silicon substrate 600, and first conductive layers 610A and 610B are embedded in recesses of the insulating layer 620. The first conductive layers 610A and 610B are formed in parallel. Second conductive layers 630A and 630B are formed on the pattern of the first conductive layers 610A and 610B and the insulating layer 620. The first conductive layers 610A and 610B and the second conductive layers 630A and 630B are, for example, metal wirings.

In steps S1 and S3, the ionic liquid is supplied to the surface of the prepared substrate W. In steps S2 and S4, the probe at the tip end of the electrode 216 connected to the power supply device 215 is brought into contact with the second conductive layers 630A and 630B located directly above the first conductive layers 610A and 610B based on the positions of the first conductive layers 610A and 610B monitored by the camera 218. In step S5, a current is caused to flow from the power supply device 215 to the first conductive layers 610A and 610B via the ionic liquid.

In step S6, due to the difference in adhesion between the insulating layer 620 and the second conductive layers 630A and 630B and the adhesion between the first conductive layers 610A and 610B and the second conductive layers 630A and 630B, the second conductive layers 630A and 630B on the insulating layer 620 are peeled off from the surface of the substrate W. As a result, as shown in FIG. 8B, the second conductive layers 630A and 630B remain only on the first conductive layers 610A and 610B, thereby forming the pattern of the second conductive layers 630A and 630B.

### Pattern Forming Method Using Pattern Forming Apparatus According to Second Embodiment

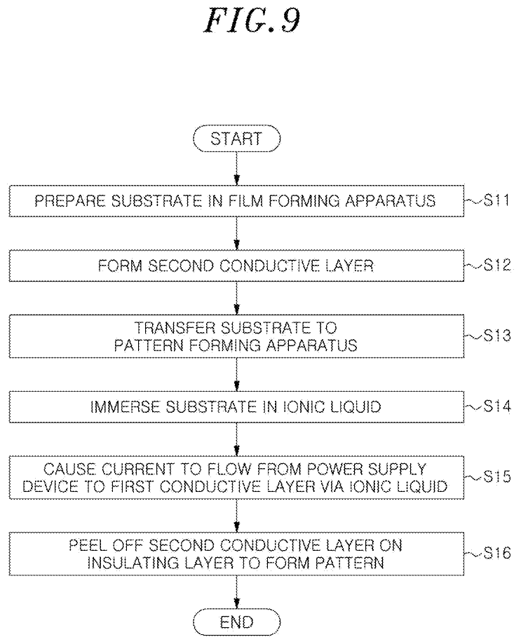

An example of a pattern forming method using the pattern forming apparatus 200a according to the second embodiment will be described with reference to FIG. 9. FIG. 9 is a flowchart illustrating an example of the pattern forming method using the pattern forming apparatus 200a according to the second embodiment. The pattern forming method shown in FIG. 9 is controlled by the controller 290.

In the pattern forming method of FIG. 9, in step S11, the substrate W on which the pattern of the first conductive layer and the insulating layer is formed is transferred to the film forming apparatus 300 and prepared.

In step S12, a second conductive layer is formed on the surface of the substrate W.

In step S13, the substrate W on which the second conductive layer is formed is transferred to the pattern forming apparatus 200a.

In step S14, the ionic liquid is supplied to the processing tank 212a, and the surface of the substrate W is immersed in the ionic liquid.

In step S15, the probe at the tip end of the electrode 216 connected to the power supply device 215 is brought into contact with the metal plate 213 provided at the bottom surface of the processing tank 212a. The other electrode 217 connected to the power supply device 215 is inserted into the ionic liquid. The backside and the front surface of the substrate W are electrically connected. Therefore, a current from the power supply device 215 is caused to flow to the first conductive layer through the ionic liquid I from the backside of the substrate W in contact with the metal plate 213.

In step S16, due to the difference in adhesion between the insulating layer and the second conductive layer and the adhesion between the first conductive layer and the second conductive layer, the second conductive layer on the insulating layer is peeled off from the surface of the substrate W, thereby forming a pattern of the second conductive layer on the first conductive layer.

### Process Application Example

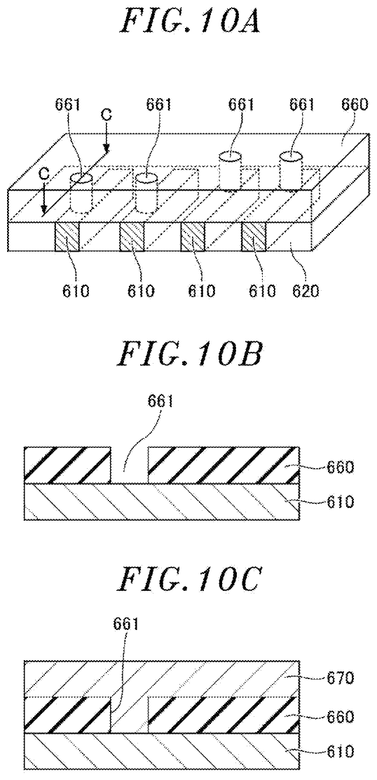

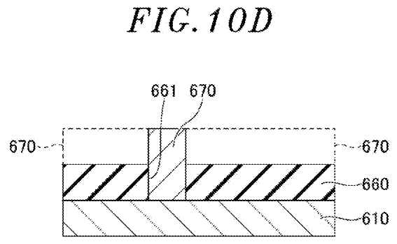

FIGS. 10A to 10D show an example of application of the pattern forming method according to the second embodiment to a process. FIG. 10B shows the C-C cross-section of FIG. 10A. The prepared substrate W includes a first layer having a pattern of the first conductive layer 610 and the insulating layer 620, and a second layer 660 formed on the first layer, as shown in FIGS. 10A and 10B. The second layer 660 is an insulating layer, and has a hole 661 that penetrates therethrough down to the first conductive layer 610 of the first layer. The insulating layer 620 and the second layer 660 are, for example, Low-k films. The first conductive layer 610 is a metal film.

In steps S11 and S12, a second conductive layer 670 is formed on the surface of the substrate W prepared in the film forming apparatus 300. As a result, as shown in FIG. 10C, the second conductive layer 670 is formed in the hole 661 and on the second layer 660.

In steps S13 to S15, the substrate W transferred to the pattern forming apparatus 200a is immersed in the ionic liquid, and a current is caused to flow to the first conductive layer 610 from the power supply device 215 through the ionic liquid. Accordingly, in step S16, due to the difference in adhesion between the second layer 660 and the second conductive layer 670 and the adhesion between the first conductive layer 610 and the second conductive layer 670, the second conductive layer 670 on the second layer 660 is peeled off from the surface of the substrate W. As a result, as shown in FIG. 10D, the second conductive layer 670 remains only in the hole 661 on the first conductive layer 610 and directly on the first conductive layer 610, thereby forming the pattern of the second conductive layer 670.

As described above, according to the pattern forming method and the pattern forming apparatus of the first and second embodiments, the pattern of the second conductive layer can be formed on the first conductive layer by utilizing the difference in adhesion between the layers on the substrate where the pattern of the first conductive layer and the insulating layer is formed.

### Other Applications

### Ionic Liquid

The ionic liquid is selected from multiple combinations of cations and anions that are liquid at room temperature. Since it is considered that cations mainly contribute to the peeling of the second conductive layer, for example, the following combinations of anions and cations may be used as the ionic liquid.
Cations: pyrrolidinium salts such as 1-ethyl-1-methylpyrrolidinium, imidazolium salts such as 1-ethyl-3-methylimidazolium
Anions: Al₂Cl₇, AlCl₄, BF₄, PF₆

### Voltage Value/Current Density

The current density and/or voltage value applied from the power supply device to the first conductive layer via the ionic liquid may be at least one of a current density of 500 mA/cm² or less, or a voltage value of 15 V or less. This is because if at least one of the current density or the voltage value controlled by the power supply device does not satisfy the above conditions, the ionic liquid may deteriorate, or devices such as metal wirings formed on the substrate W may be adversely affected. More preferably, the current density and/or voltage value applied from the power supply device to the first conductive layer via the ionic liquid may be at least one of a current density of 50 mA/cm² or less, or a voltage value of 5 V or less. Accordingly, the possibility of damaging the ionic liquid or adversely affecting devices on the substrate W may be reduced.

### Other Process Application Examples

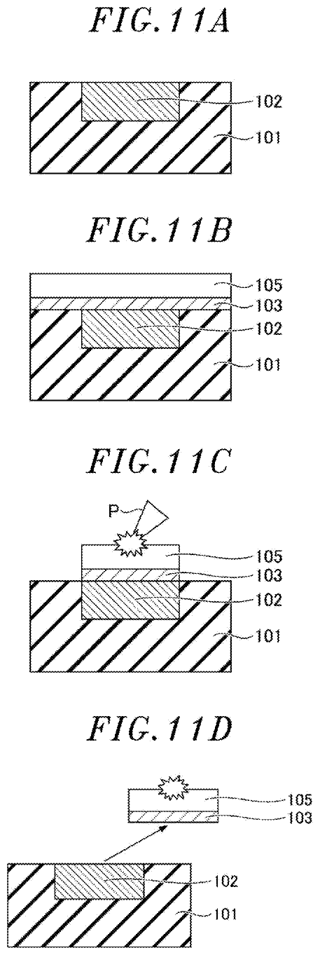

Other process application examples will be described with reference to FIGS. 11A to 11D. FIGS. 11A to 11D illustrate other process application examples. In manufacturing processes, a probe needle is applied to the wiring for inspection. Therefore, physical contact of the probe needles with the wiring may cause damage to the wiring.

Therefore, as shown in FIG. 11B, a dummy pad 105 is formed via the second conductive layer 103 on the pattern of the insulating layer 101 that is a Low-k film, and the first conductive layer 102 that is a wiring layer, shown in FIG. 11A. Similarly to the case where another film 104 is formed on the second conductive layer 103 shown in FIG. 2A, in the dummy pad 105, the pattern formation utilizing the difference in adhesion between layers can be performed by the pattern formation on the substrate using an ionic liquid, as shown in FIG. 11C. In other words, only the second conductive layer 103 and the dummy pad 105 on the first conductive layer 102, which have higher adhesion, selectively remain, whereas the second conductive layer 103 and the dummy pad 105 on the insulating layer 101, which have lower adhesion, are peeled off at once, thereby forming the second conductive layer 103 and the dummy pad 105 on the pattern of the first conductive layer 102.

As the material for the second conductive layer 103, a noble metal such as gold, silver, platinum, palladium, rhodium, iridium, ruthenium, or osmium may be used. As the material for the first conductive layer 102, wiring materials such as Cu, W, TiN, Al, or Co may be used.

In this case, during the inspection of the manufacturing process, a probe needle P is applied to the dummy pad 105 shown in FIG. 11C, so that the probe needle is not physically brought into contact with the first conductive layer 102. Therefore, the inspection can be performed without damaging the first conductive layer 102.

As Shown in FIG. 11D, the damaged dummy pad 105 is removed later. In this case, the dummy pad 105 can be removed by CMP or wet etching. The pattern forming method on the substrate using an ionic liquid is not employed for the removal of the dummy pad 105.

The pattern forming method and the pattern forming apparatus according to the embodiments of the present disclosure are considered to be illustrative in all respects and not restrictive. The above-described embodiments can be changed and modified in various forms without departing from the scope of the appended claims and the gist thereof. The above-described embodiments may include other configurations without contradicting each other and may be combined without contradicting each other.

This application claims priority to Japanese Patent Application No. 166462 filed on Sep. 27, 2023, the entire contents of which are incorporated herein by reference.

1. A pattern forming method comprising:
preparing a substrate having a second conductive layer on a surface of the substrate on which a pattern of a first conductive layer and an insulating layer is formed;
supplying an ionic liquid to the surface of the substrate; and
forming a pattern of the second conductive layer on the first conductive layer by causing a current to flow to the first conductive layer to which the ionic liquid has been supplied.

2. The pattern forming method of claim 1, wherein said forming the pattern includes forming the pattern of the second conductive layer by peeling off the second conductive layer on the insulating layer.

3. The pattern forming method of claim 1, wherein the second conductive layer is any one of a noble metal, tungsten, molybdenum, or copper.

4. The pattern forming method of claim 3, wherein the second conductive layer is a noble metal.

5. The pattern forming method of claim 4, wherein the noble metal is any one of gold, silver, platinum, palladium, rhodium, iridium, ruthenium, or osmium.

6. The pattern forming method of claim 1, further comprising:
forming the second conductive layer on the surface of the substrate before preparing the substrate.

7. The pattern forming method of claim 6, further comprising:
forming another film on the second conductive layer after forming the second conductive layer and before preparing the substrate.

8. The pattern forming method of claim 1, wherein causing the current to flow to the first conductive layer includes, when a back surface of the substrate and the surface of the substrate are electrically connected, bringing a probe connected to a power supply device into contact with the back surface and causing the current to flow to the first conductive layer through the ionic liquid.

9. The pattern forming method of claim 1, further comprising:
monitoring a position of the first conductive layer,
wherein causing the current to flow to the first conductive layer includes bringing a probe connected to a power supply device into contact with the second conductive layer directly on the monitored first conductive layer and causing the current to flow to the first conductive layer through the ionic liquid.

10. The pattern forming method of claim 1, wherein a current density applied to the first conductive layer is 500 mA/cm² or less, and/or a voltage value applied to the first conductive layer is 15 V or less.

11. The pattern forming method of claim 10, wherein the current density applied to the first conductive layer is 50 mA/cm² or less, and/or the voltage value applied to the first conductive layer is 5 V or less.

12. A pattern forming apparatus comprising:
a chamber;
a processing tank disposed in the chamber;
a power supply device; and
a controller,
wherein the controller controls:
preparing, in the processing tank, a substrate having a second conductive layer on a surface of the substrate on which a pattern of a first conductive layer and an insulating layer is formed;
supplying an ionic liquid to the surface of the substrate in the processing tank; and
forming a pattern of the second conductive layer on the first conductive layer by causing a current to flow from the power supply device to the first conductive layer to which the ionic liquid has been supplied.

13. The pattern forming method of claim 1, wherein said supplying the ionic liquid comprises immersing the substrate by accommodating the substrate in a processing tank provided in a chamber and supplying the ionic liquid into the processing tank.

14. The pattern forming method of claim 13, further comprising evacuating an interior of the chamber to not more than 1 Pa before supplying the ionic liquid.

15. The pattern forming method of claim 1, further comprising, before said supplying the ionic liquid, bubbling an inert gas into the ionic liquid to reduce a dissolved oxygen concentration in the ionic liquid.

16. The pattern forming method of claim 15, wherein the inert gas is nitrogen gas.

17. The pattern forming method of claim 1, further comprising detecting a change in electrical resistance while the current is caused to flow, and stopping application of the current when a predetermined resistance change is detected.

18. The pattern forming method of claim 1, wherein the first conductive layer comprises TiN or TaN.

19. The pattern forming method of claim 7, wherein the another film is a silicon dioxide film or a silicon nitride film.

20. The pattern forming method of claim 1, wherein said supplying the ionic liquid comprises spraying the ionic liquid while rotating the substrate.
